(19) United States
(12) Patent Application Publication
(10) Pub. No.: US 2004/0241889 A1
(43) Pub. Date: Dec. 2, 2004

(54) Method and system of beam energy control

(75) Inventors: Long-Sheng Liao, Jungli City (TW); Chien-Chou Hsu, Kaohsiung (TW); Yi-Chang Tsao, Hsinchu (TW)

Correspondence Address: Richard P. Berg, Esq., c/o LADAS & PARRY, Suite 2100, 5670 Wilshire Boulevard, Los Angeles, CA, 90036-5679, US

(73) Assignee: AU Optronics Corp.

(21) Appl. No.: 10/751,238

(22) Filed: Dec. 30, 2003

(30) Foreign Application Priority Data
Jan. 7, 2003 (TW) 92100246

(51) Int. Cl. H01L 21/66

(52) U.S. Cl. 438/14

(57) ABSTRACT

A method and system of automatic beam energy control. First, a substrate is provided. Next, hydrogen content of the substrate is measured to determine whether hydrogen content exceeds a critical hydrogen content limit. A warning is issued when hydrogen content exceeds a critical hydrogen content limit. Substrate thickness is measured when hydrogen content does not exceed a critical hydrogen content limit. A database comprising a plurality of beam energy values individually absorbed by substrates of different thicknesses is provided. An appropriate beam energy level corresponding to the measured thickness is provided by the database. Finally, beam energy is delivered to the substrate accordingly.

### BACKGROUND OF THE INVENTION

1. Field of the Invention

The present invention relates to a thin film transistor manufacturing process and in particular to a method of controlling the beam energy employed therein.

2. Description of the Related Art

Thin film transistors (TFT) are widely used to drive conventional liquid crystal display devices. Usually, a thin film transistor (TFT) comprises an amorphous silicon thin film transistor (a-Si:H TFT) and a polysilicon thin film transistor (poly-Si TFT) divided into a high temperature poly silicon (HTPS) transistor and a low temperature poly silicon (LTPS) transistor.

Conventionally, in the manufacturing process of the low temperature poly silicon (LTPS) transistor, excimer laser annealing (ELA) is usually performed on amorphous silicon, such that amorphous silicon is recrystallized as crystal silicon. The crystal silicon is subsequently processed for a transistor. Accordingly, ELA is a key technique when manufacturing low temperature poly silicon (LTPS).

However, the amount of beam energy absorbed by amorphous silicon for crystallization depends on the thickness of amorphous silicon. Different amounts of beam energy are absorbed by amorphous silicon of different thicknesses. Thus, the beam energy has to be controlled depending on the thickness of amorphous silicon. Furthermore, hydrogen explosion can occur during ELA when the hydrogen content exceeds the critical hydrogen content limit, depending on the material. Both thickness and hydrogen content must be measured and referenced before ELA.

### SUMMARY OF THE INVENTION

Accordingly, an object of the present invention is to provide a method and system of automatic beam energy control, such that not only can thickness and hydrogen content of an amorphous silicon be measured, but also ELA can be performed.

Another object of the present invention is to provide a method and system of automatic beam energy control to provide appropriate beam energy in amorphous silicon of different thicknesses, such that amorphous silicon can reconstitute as crystal silicon.

Still another object of the present invention is to provide a method and system of automatic beam energy control to avoid hydrogen explosion during ELA.

Further, another object of the present invention is to provide a method and system of automatic beam energy control to reduce failure in the silicon substrate after ELA and enhance yield.

One feature of the present invention is determination of whether hydrogen content of amorphous silicon is less than the critical hydrogen content limit to avoid hydrogen explosion before ELA. The critical hydrogen content limit of amorphous silicon varies with thickness. When the hydrogen content exceeds the critical hydrogen content limit, hydrogen explosion occurs during ELA.

Another feature of the present invention is to set up a database of beam energy absorbed by amorphous silicon of different thicknesses during crystallization. The appropriate beam energy is found and provided to the amorphous silicon after checking the hydrogen content.

To achieve the above objects, one aspect of the present invention provides a method of automatic beam energy control. First, a substrate is provided. Next, hydrogen content of the substrate is measured. A warning is issued when hydrogen content exceeds a critical hydrogen content limit. Substrate thickness is measured when hydrogen content does not exceed the critical hydrogen content limit. A database comprising a plurality of beam energy values individually absorbed by substrates of different thicknesses is set up. A beam energy value corresponding to the measured thickness is estimated by the database. Finally, a beam energy level is provided for the substrate accordingly.

Another aspect of the present invention provides a system of automatic beam energy control, comprising a substrate holding apparatus, a measurement apparatus, a comparing apparatus, and a energy beam apparatus. The measurement apparatus measures thickness and hydrogen content of the substrate in the substrate holding apparatus. The comparing apparatus provides a database comprising critical hydrogen content limits and appropriate beam energy levels for substrates of different thicknesses, allowing determination of whether a measured hydrogen content value exceeds the critical hydrogen content limit and to provide an appropriate beam energy level. The energy beam apparatus delivers beam energy to the substrate accordingly.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a block diagram illustrating the system of automatic beam energy control according to one embodiment of the invention;

FIG. 2 is a flowchart illustrating the method of automatic beam energy control according to one embodiment of the invention.

### DETAILED DESCRIPTION OF THE INVENTION

A preferred embodiment of the present invention is now described with reference to the figures.

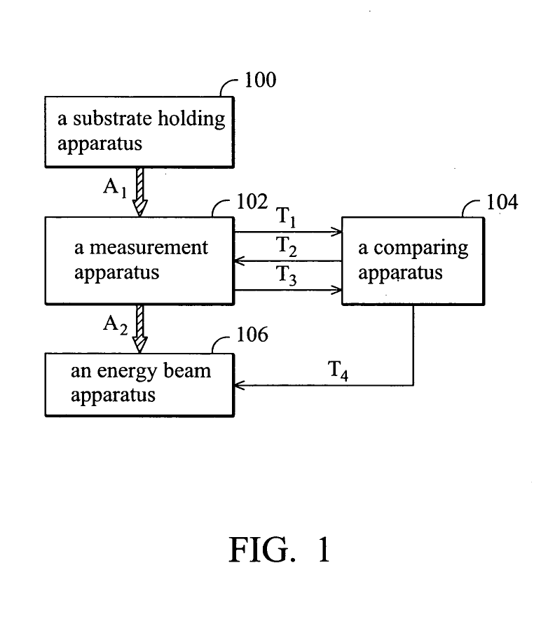

FIG. 1 illustrates the system of automatic beam energy control according to one embodiment of the present invention. The system comprises a substrate holding apparatus 100, a measurement apparatus 102, a comparing apparatus 104, and a energy beam apparatus 106.

The substrate holding apparatus 100 fixes a substrate, such as amorphous silicon suitable for a thin film transistor (TFT). The substrate can be transported to the measurement apparatus 102 and a energy beam apparatus 106 by the substrate holding apparatus 100.

The measurement apparatus 102 measures thickness and hydrogen content of the substrate. The measurement apparatus 102 preferably uses ellipsometry to measure a light extinction coefficient of the substrate, such that hydrogen content is calculated in accordance with the relationship between the light extinction coefficient and a bandgap of the substrate. As well, thickness is calculated in accordance with a refractive index of the substrate, also measurable using ellipsometry.

In Amorphous and Liquid Semiconductors, Tauc J., 1974, proposes the following formula.

$${N}_{H} = C \cdot A {\int }_{ω} [ α ( ω ) / ω ] ⅆ ω$$

$$α ( ω ) = {B ( ℏω - {E}_{g}^{OPT} )}^{2} / ℏω$$

$$A = {[ 1 + 2 ( {ϵ}_{s} / {ϵ}_{0} ) ]}^{2} {( {ϵ}_{s} / {ϵ}_{0} )}^{1 / 2} / 9 {( {ϵ}_{s} / {ϵ}_{0} )}^{2}$$

$$\text{for} aSi {ϵ}_{s} / {ϵ}_{0} = 12$$

N_{H} indicates hydrogen content of an amorphous silicon, and α(ω) is an absorbing coefficient, a function of light frequency. εₛ is a dielectric constant of a material, and ε₀ is the dielectric constant in a vacuum. E_{g}^{OPT} is the energy bandgap of amorphous silicon. B, C, h are all constant.

The hydrogen content N_{H} is relative to the absorption coefficient α(ω) and energy bandgap E_{g}^{OPT}. Extinction coefficient k, reflection index n, and thickness can all be measured by ellipsometry. Furthermore, k=[λα(ω)]/(4π). Thus, ellipsometry can be employed to not only measure thickness, but also hydrogen content.

The comparing apparatus 104, comprising a computer, provides a database of critical hydrogen content limits and appropriate beam energy levels for substrates of different thicknesses. Hydrogen content T₁ measured by measurement apparatus 102 is provided to the comparing apparatus 104, as shown in FIG. 1. The comparing apparatus 104 issues a warning or alarm when hydrogen content T₁ exceeds the critical hydrogen content limit. According to the path of T2, the comparing apparatus 104 instructs the measurement apparatus 102 to measure thickness T₃ when hydrogen content T₁ does not exceed the critical hydrogen content limit. The amorphous silicon substrate is transported to the measurement apparatus 102 by the substrate holding apparatus 100 according to the path of A₁. Thickness T₃ measured by the measurement apparatus 102 is then provided to the comparing apparatus 104. According to thickness T₃, the appropriate beam energy level of amorphous silicon is determined by the comparing apparatus 104. According to the path of T4, the appropriate beam energy level is provided to the energy beam apparatus 106 by the comparing apparatus 104.

The energy beam apparatus 106 delivers beam energy to the substrate for ELA. The amorphous silicon substrate is transported to the energy beam apparatus 106 by the substrate holding apparatus 100 according to the path of A₂. After the appropriate beam energy level is received, ELA is performed in the amorphous silicon substrate by the energy beam apparatus 106 accordingly.

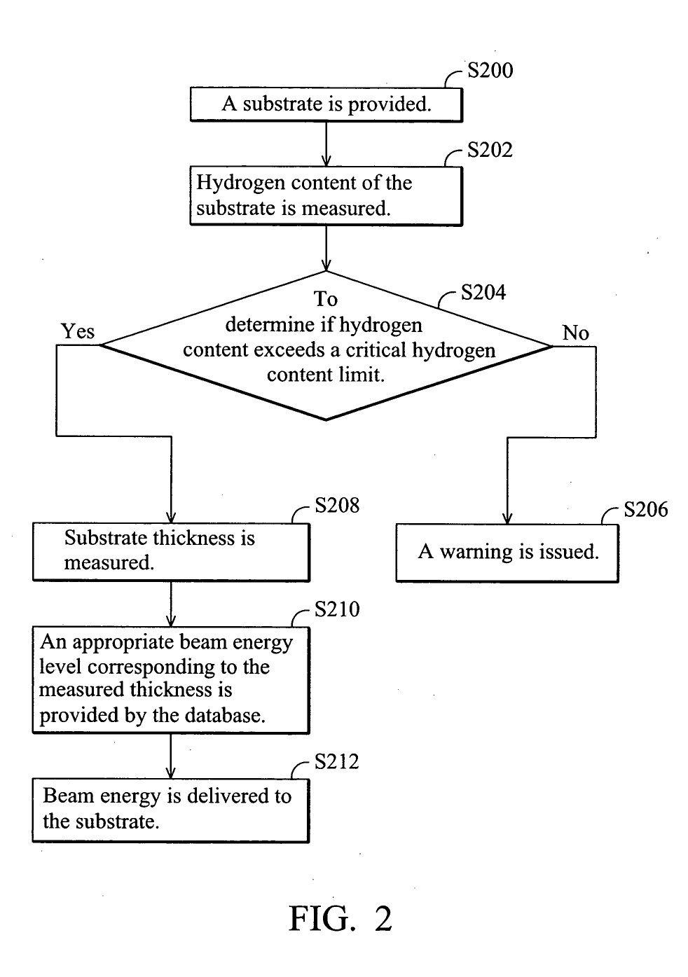

FIG. 2 is a flowchart of the method of automatic beam energy control according to one embodiment of the present invention.

In step S200, the substrate is provided on the substrate holding apparatus 100.

Next, in step S202, a hydrogen content value T₁ of the substrate is measured by the measurement apparatus 102 after the substrate is transported to the measurement apparatus 102 by the substrate holding apparatus 100.

In step S204, the result of hydrogen content T₁ is transported to the comparing apparatus 104 to determine if hydrogen content T₁ exceeds a critical hydrogen content limit.

In step S206, a warning or alarm is issued when hydrogen content T₁ exceeds a critical hydrogen content limit.

In step S208, thickness T₃ of the substrate is measured when hydrogen content T₁ does not exceed a critical hydrogen content limit.

In step S210, the appropriate beam energy level T₄ for amorphous silicon of a certain thickness T₃ is determined by the comparing apparatus 104 after measuring thickness T₃. Requisite beam energy levels for amorphous silicon of varying thicknesses are shown in Table 1. The appropriate beam energy level T₄ is provided to the energy beam apparatus 106.

TABLE 1

| Appropriate beam | Thickness of |
|---|---|
| energy level (mJ) | amorphous silicon (Å) |
| 200 | 100 |
| 210 | 200 |
| 220 | 300 |
| 250 | 400 |
| 270 | 500 |
| 290 | 600 |
| 310 | 700 |
| 350 | 800 |
| 400 | 900 |
| 460 | 1000 |

Finally, in step S212, beam energy is provided to the substrate according to the beam energy value T₄ by the energy beam apparatus 106. Thus, amorphous silicon becomes crystal silicon after ELA.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system of automatic beam energy control, comprising:
a substrate holding apparatus, holding a substrate;
a measurement apparatus, measuring thickness and hydrogen content of the substrate; and
a comparing apparatus, providing a database further comprising critical hydrogen content limits and appropriate beam energy levels for substrates of different thicknesses, allowing determination of whether a measured hydrogen content value exceeds a critical hydrogen content limit, providing an appropriate beam energy level accordingly; and
a energy beam apparatus, delivering beam energy to the substrate accordingly.

2. The system as claimed in claim 1, wherein the measurement apparatus utilizes ellipsometry.

3. The system as claimed in claim 1, wherein the comparing apparatus issues a warning or alarm when hydrogen content exceeds a critical hydrogen content limit.

4. The system as claimed in claim 1, wherein the comparing apparatus instructs the measurement apparatus to measure thickness when the hydrogen content does not exceed the critical hydrogen content limit.

5. The system as claimed in claim 1, wherein hydrogen content is calculated in accordance with the relationship between a light extinction coefficient and a bandgap of the substrate.

6. The system as claimed in claim 1, wherein thickness is calculated in accordance with a refractive index of the substrate.

7. The system as claimed in claim 1, wherein the substrate comprises amorphous silicon.

8. The system as claimed in claim 7, wherein the database comprises appropriate beam energy levels required by different thicknesses of amorphous silicon for reconstitution into crystal silicon.

9. A method of automatic beam energy control, comprising:
providing a substrate;
measuring hydrogen content of the substrate;
determining if hydrogen content exceeds a critical hydrogen content limit;
issuing a warning or alarm when hydrogen content exceeds a critical hydrogen content limit;
measuring substrate thickness when hydrogen content does not exceed a critical hydrogen content limit;
providing a database comprising a plurality of appropriate beam energy values corresponding to substrates of different thicknesses;
the database determining an appropriate beam energy level corresponding to the measured thickness; and
delivering beam energy to the substrate accordingly.

10. The method as claimed in claim 9, wherein thickness is calculated by measuring a refractive index of the substrate using a reflection meter.

11. The method as claimed in claim 10, wherein thickness is calculated by measuring a refractive index of the substrate using ellipsometry.

12. The method as claimed in claim 9, wherein hydrogen content is calculated in accordance with the relationship between a light extinction coefficient and a bandgap by measuring the light extinction coefficient of the substrate using ellipsometry.

13. The method as claimed in claim 9, wherein the substrate comprises amorphous silicon.

14. The method as claimed in claim 9, wherein the database is populated by determining appropriate beam energy levels required by different thicknesses of amorphous silicon for reconstitution into crystal silicon.

15. A method of automatic beam energy control, comprising:
providing a substrate on a substrate holding apparatus;
measurement of substrate hydrogen content by ellipsomety;
determining if hydrogen content exceeds a critical hydrogen content limit using a comparing apparatus;
the comparing apparatus issuing a warning or alarm when hydrogen content exceeds a critical hydrogen content limit;
measurement of substrate thickness by ellipsomety when hydrogen content does not exceed a critical hydrogen content limit;
providing a database comprising a plurality of energy values individually absorbed by substrates of different thickness;
determining a beam energy value corresponding to the measured thickness according to the database, using a comparing apparatus; and
a energy beam apparatus delivering energy to the substrate accordingly.

16. The method as claimed in claim 15, wherein thickness is calculated by measuring a refractive index of the substrate.

17. The method as claimed in claim 15, wherein hydrogen content is calculated in accordance with the relationship between a light extinction coefficient and a bandgap by measuring the light extinction coefficient of the substrate.

18. The method as claimed in claim 15, wherein the substrate comprises amorphous silicon.

19. The method as claimed in claim 15, wherein the database is populated by determining appropriate energy levels required by different thicknesses of amorphous silicon for reconstitution into crystal silicon.

20. The method as claimed in claim 15, wherein amorphous silicon is reconstitute into crystal silicon after receiving the beam energy.
